(19) United States
(12) Patent Application Publication
(10) Pub. No.: US 2015/0048487 A1
(43) Pub. Date: Feb. 19, 2015

(54) PLASMA POLYMERIZED THIN FILM HAVING HIGH HARDNESS AND LOW DIELECTRIC CONSTANT AND MANUFACTURING METHOD THEREOF

(71) Applicant: RESEARCH & BUSINESS FOUNDATION SUNGKYUNKWAN UNIVERSITY, Suwon-si (KR)

(72) Inventors: Dong Geun JUNG, Seoul (KR); Hoon Bae KIM, Incheon (KR); Hyo Jin OH, Seongnam-si (KR); Chae Min LEE, Gwacheon-si (KR)

(73) Assignee: RESEARCH & BUSINESS FOUNDATION SUNGKYUNKWAN UNIVERSITY, Suwon-si (KR)

(21) Appl. No.: 14/178,065

(22) Filed: Feb. 11, 2014

(30) Foreign Application Priority Data
Aug. 19, 2013 (KR) 10-2013-0098177

(51) Int. Cl. H01L 21/02; H01L 29/06

(52) U.S. Cl. CPC H01L 21/02118; H01L 21/02274; H01L 29/06
USPC 257/632; 438/781; 524/588

(57) ABSTRACT

The present invention relates to a plasma polymerized thin film having high hardness and a low dielectric constant and a manufacturing method thereof, and in particular, relates to a plasma polymerized thin film having high hardness and a low dielectric constant for use in semiconductor devices, which has improved mechanical strength properties such as hardness and elastic modulus while having a low dielectric constant, and a manufacturing method thereof.

### CROSS REFERENCE TO RELATED APPLICATIONS

This application claims the benefit under 35 U.S.C. §119(a) of Korean Patent Application No. 10-2013-0098177 filed on Aug. 19, 2013, in the Korean Intellectual Property Office, the entire disclosure of which is incorporated herein by reference for all purposes.

### TECHNICAL FIELD

The present invention relates to a plasma polymerized thin film having high hardness and a low dielectric constant and a manufacturing method thereof, and in particular, relates to a plasma polymerized thin film having high hardness and a low dielectric constant for use in semiconductor devices, having improved mechanical strength properties such as hardness and elastic modulus while having a low dielectric constant, and a manufacturing method thereof.

### BACKGROUND ART

Currently, one of the main steps in the manufacture of semiconductor devices is the formation of metal and dielectric thin films on a substrate by a gaseous chemical reaction. This deposition process includes a chemical vapor deposition (CVD). In a typical thermal CVD process, reactant gases are provided to the surface of a substrate, and a predetermined thin film is formed on the surface of the substrate due to the occurrence of a thermally-induced chemical reaction. A thermal CVD process is conducted at a high temperature, and a device having the layer formed on the substrate may be damaged due to the high temperature. One of the methods capable of solving such a problem, that is, among methods in which metals and dielectric films are deposited at a relatively low temperature, is a plasma enhanced CVD (PECVD) method.

According to plasma enhanced CVD technology, radio frequency (RF) energy is applied to a reaction zone, and this promotes the excitation and/or dissociation of reactant gases, thereby generating plasma with highly reactive species. The high reactivity of the species in plasma reduces the energy required for a chemical reaction to take place and thus lowers the temperature required by the process. Semiconductor device structures have significantly decreased in size due to the introduction of this apparatus and method.

Meanwhile, silicon dioxide (SiO₂), which has been mainly used as an interlayer insulating film until now, has a resistance-capacitance (RC) delay time when ultra large scale integrated circuits of 0.5 μm or less are manufactured. Therefore, in order to reduce the RC delay of the multilayer metal film used for integrated circuits of a semiconductor device, research on the formation of a interlayer insulating film used for metal wires with a material having a low relative dielectric constant (×≦3.5) have been recently actively conducted. Such a thin film having a low dielectric constant is formed either with an inorganic material such as a fluorine (F)-doped oxide film (SiOF) and a fluorine-doped amorphous carbon (a-C:F) film, or with an organic material including carbon (C).

Materials having a low dielectric constant currently considered for use as a substitute for SiO₂ include SILK (available from DOW Chemical), FLARE (fluorinated poly(arylene ether), available from Allied Signals) and the like, which are mainly formed by spin coating, and SiOF, Black Diamond (available from Applied Materials), Coral (available from Novellus) and the like, which are formed by chemical vapor deposition (CVD). In addition, organic polymers such as polyimide, and porous thin film materials such as xerogel or aerogel are also included.

Herein, the material having a low dielectric constant, which is formed using a spin casting method in which the material is cured after being spin coated, is formed to a dielectric substance having a low dielectric constant since pores having a size of few nanometers (nm) are formed within the film resulting in the density decrease in the thin film. Generally, the polymers deposited by spin coating have advantages in that they usually have a low dielectric constant and excellent planarization. However, polymers are not suitable to be applied to a semiconductor since they have a heat-resistant threshold temperature lower than 450° C., thereby having poor thermal stability, and particularly, polymers have various problems in the manufacture of devices since the mechanical strength of the thin film is low due to the size of the pores being large and the pores not being uniformly distributed within the film. In addition, polymers have problems in that they have poor contact with upper and lower wiring materials, high stress due to thermal curing. Further, the reliability of devices is reduced due to dielectric constant changes attributable to the absorption of water present in the surroundings.

Meanwhile, the inventors of the present invention have conducted a study on a thin film using a PECVD method with hexamethyldisiloxane and 3,3-dimethyl-1-butene as precursors, and considerably improved the dielectric constant of the thin film (Korean Patent Number 10-0987183). However, there remained a problem in that the mechanical properties of the thin film were not satisfactory.

### DISCLOSURE

### Technical Problem

In view of the above, the inventors of the present invention have verified that, when a thin film is manufactured by depositing a cross-shaped precursor, mechanical strength properties such as hardness and elastic modulus are considerably improved compared to conventional thin films while still maintaining a low electric constant. The present invention is based on this discovery.

### Technical Solution

A first aspect of the present invention provides a plasma polymerized thin film having high hardness and a low dielectric constant manufactured using a first precursor represented by the following Chemical Formula 1.

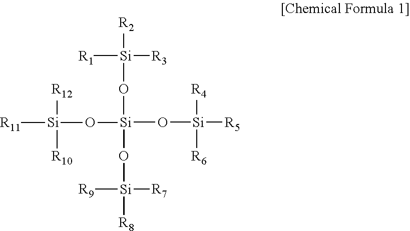

In the formula, R₁ to R₁₂ are each independently H or C₁-C₅ alkyl.

A second aspect of the present invention provides a method for manufacturing a plasma polymerized thin film having high hardness and a low dielectric constant, which includes a first step of depositing the plasma polymerized thin film on a substrate by polymerizing a first precursor represented by Chemical Formula 1 through plasma; and a second step of annealing the deposited thin film.

A third aspect of the present invention provides a semiconductor device equipped with an insulating layer consisting of the plasma polymerized thin film having high hardness and a low dielectric constant of the first aspect.

Hereinafter, the present invention will be described in detail.

In the present invention, a cross-shaped precursor represented by Chemical Formula 1 may be used as a precursor for forming a thin film, and by depositing the thin film having the polymerized precursor, a thin film having improved mechanical strength while maintaining a low dielectric constant can be provided. The thin film according to the present invention has high hardness and elastic modulus, and therefore, improvement in chemical mechanical planarization (CMP) process is possible, and since the thin film also has a low dielectric constant, resistance-capacitance (RC) delay time occurring in the manufacture of ultra large scale integrated circuits can be reduced.

Furthermore, the thin film according to the present invention can simplify pre- and post-treatments or complicated related processes which occur in spin casting methods. In addition, the properties of a plasma polymerized thin film can be improved by annealing the thin film using a rapid thermal annealing (RTA) apparatus.

The first precursor according to the present invention, which is represented by Chemical Formula 1, has a feature of the whole compound structure forming a cross shape in which a Si atom at the center is linked to oxygen atoms in four directions. As a result, in the thin film manufactured using the first precursor, Si—O bonding can be solidly maintained compared to other bonding due to such structural characteristics. Therefore, improvement in the hardness and the elastic modulus of the thin film can be maintained even after the thin film is annealed.

In addition, in the present invention, the thin film can be deposited using the first precursor and a second precursor, which is hydrocarbon in a liquid state, at the same time, and in this case, cross-linking between the first precursor molecules and the second precursor molecules can readily occur. Therefore, when the thin film is deposited combining these precursors, complex cross-linking is possible, and further, polymer polymerizations by plasma can readily occur. The plasma polymerized thin film according to the present invention, which is manufactured as above, can have excellent thermal stability and improved mechanical properties while maintaining a low dielectric constant.

The plasma polymerized thin film having high hardness and a low dielectric constant according to the first aspect of the present invention is manufactured using a first precursor represented by the following Chemical Formula 1.

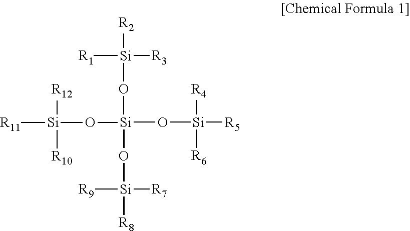

In the formula, R₁ to R₁₂ are each independently H or C₁-C₅ alkyl.

Furthermore, the plasma polymerized thin film having high hardness and a low dielectric constant may be manufactured using a second precursor, which is hydrocarbon in a liquid state present within a bubbler of a plasma polymerization apparatus, together with the first precursor.

Regarding the first precursor, R₁ to R₁₂ in Chemical Formula 1 may be each independently H or C₁-C₅ alkyl, and examples of the alkyl include methyl, ethyl, propyl, butyl and the like. These alkyls may be linear or branched.

In one example of the present invention, the first precursor represented by Chemical Formula 1 may be tetrakis(trimethylsilyloxy)silane in which each of R₁ to R₁₂ is methyl as represented by the following Chemical Formula 2.

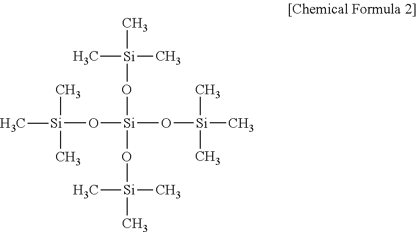

The first precursor is preferably deposited together with other precursors, and an example thereof includes a second precursor.

The second precursor may be hydrocarbon in a liquid state present within a bubbler of a plasma polymerization apparatus. When the second precursor is hydrocarbon, it has advantages in that the second precursor can show favorable linking power with the first precursor, the plasma polymerized thin film is readily formed, and the hardness and the elasticity of the thin film is improved due to the presence of multiple C—Hₓ bonding structures. Furthermore, the plasma polymerized thin film of the present invention may be formed using a plasma polymerization apparatus (for example, a PECVD apparatus), therefore, the second precursor is preferably hydrocarbon that can be in a liquid state within the bubbler of the plasma polymerization apparatus. The bubbler can store a precursor and also vaporize the precursor present inside. The bubbler can store more amounts of the precursor when the precursor is in a liquid state than in a gas state, and it may be suitable considering the liquid vaporization function of the bubbler.

Generally, the conditions within the bubbler may be standard (25° C. and 1 atmosphere), however, the conditions may also be 250° C. or less and 5 atmosphere or less by controlling the temperature and the pressure.

The second precursor is not particularly limited as long as it is hydrocarbon in a liquid state present within the bubbler, however, more specifically, it may include hydrocarbon such as C₆-C₁₂ alkane, alkene, cycloalkane or cycloalkene. If the carbon number of the second precursor is less than C₆, it is difficult for the second precursor to be in a liquid state in standard conditions, therefore, the temperature needs to be lowered and the pressure must be raised within the bubbler, and since the second precursor has a low molecular weight, the cross-linking power with the first precursor decreases and as a result, there may be a problem in that the thin film is not readily deposited. Meanwhile, if the carbon number of the second precursor is greater than C₁₂, the second precursor can be in a solid state in normal conditions, therefore the temperature needs to be raised and the pressure to be lowered within the bubbler, and there may be a problem in that it is difficult for evaporation to occur in the bubbler.

One preferable example of the second precursor includes cyclohexane, which is a ring-shape organic compound, but the precursor is not limited thereto.

The first precursor and the second precursor can be combined at the same time and used, and they can readily form cross-linking due to their chemical and structural characteristics as described above to thereby increase the stability of the thin film, therefore, a plasma polymerized thin film having improved mechanical properties while maintaining a low dielectric constant can be provided.

The plasma polymerized thin film according to the present invention may be manufactured by a polymerization reaction using plasma. In this case, it may be additionally used together with the second precursor. Specifically, by the plasma generated within a reactor for plasma deposition, the thin film may be formed through polymerization between the first precursors or between the first precursor and the second precursor. The polymerization reaction using plasma can form the thin film on a substrate within a reactor by the first precursor and the second precursor being effectively polymerized and deposited through the generation of plasma including highly reactive species. Based on the principle described above, as shown in FIG. 9, the polymerization reaction using plasma has higher cross-linking density compared to general polymerization reactions. Furthermore, when the plasma polymerized thin film is formed, a gap of a nanometer size or less may be formed resulting in the reduction of the dielectric constant and the improvement in the mechanical properties. One example of the polymerization reactions using plasma includes a plasma enhanced chemical vapor deposition (PECVD) method.

When the thin film is formed through the polymerization reaction using plasma, the thin film having the first precursor and the second precursor present in a certain ratio may be formed by supplying the precursors in the certain ratio. Furthermore, the supplied amount or the intended ratio of the supplied first precursor to the second precursor may be determined by adjusting the temperature of a bubbler, or the flow rate of a carrier gas such as helium (He). For example, the thin film may be deposited with the flow rate ratio of a first carrier gas:a second carrier gas corresponding to the intended ratio of the first precursor (bubbler temperature 90° C.) and the second precursor (bubbler temperature 55° C.) to be 1:1 to 1:5. If the flow rate ratio of the second carrier gas is greater than 5 times with respect to the first carrier gas, SiOx within the thin film is significantly reduced and the thin film is difficult to be used as an interlayer insulating film, and if the flow rate ratio of the second carrier gas is less than the flow rate ratio of the first carrier gas, the dielectric constant or the mechanical strength may not be significantly improved.

Furthermore, the plasma polymerized thin film may be annealed using an RTA apparatus after being deposited through the polymerization reaction using plasma. By conducting the annealing, it was verified that the dielectric constant of the plasma polymerized thin film according to the present invention significantly decreased (FIG. 4).

The plasma polymerized thin film according to the present invention manufactured using the method and the precursor as above may have a thickness ranging from 0.1 μm to 1.5 μm. If the thickness is less than 0.1 μm, there may be a problem in that there may be difficulties in manufacturing and processing, and the hardness of the thin film may be reduced, and if the thickness is greater than 1.5 μm, manufacturing costs may increase and there may be difficulties in manufacturing ultra large scale integrated circuits. Furthermore, the plasma polymerized thin film according to the present invention may have high hardness and a low dielectric constant, with the mechanical strength (hardness) ranging from 0.1 to 10 GPa and the relative dielectric constant ranging from 1.5 to 3.5.

A second aspect of the present invention is a method for manufacturing a plasma polymerized thin film having high hardness and a low dielectric constant, and the method includes a first step of depositing the plasma polymerized thin film on a substrate by polymerizing a first precursor represented by Chemical Formula 1 through plasma; and a second step of annealing the deposited thin film.

Furthermore, the first step may be depositing the plasma polymerized thin film on a substrate by polymerizing a second precursor, which is hydrocarbon in a liquid state present within a bubbler of a plasma polymerization apparatus, together with the first precursor.

The first precursor, the second precursor, the thin film and the like in the method for manufacturing the plasma polymerized thin film according to the present invention are the same as those described above in the first aspect.

The first step is a step in which the plasma polymerized thin film is formed on a substrate by polymerizing and depositing the first precursor under plasma using a plasma polymerization apparatus, and at this time, the second precursor may be used together.

Herein, the first step in which the plasma polymerized thin film is deposited on a substrate may include an A step of vaporizing the first precursor and the second precursor in bubblers; a B step of supplying the vaporized precursors into a reactor for plasma deposition from the bubblers; and a C step of forming the plasma polymerized thin film on the substrate in the reactor using plasma of the reactor.

One example of the plasma polymerization apparatus includes a PECVD apparatus using a PECVD method. The apparatus conducts a thin film deposition process through a process chamber constituted of an upper chamber lid and a lower chamber body, that is, a reactor. The thin film is deposited by uniformly spraying reactant gases onto a substrate, which is safely placed on the upper surface of a susceptor formed in the chamber body, through shower heads formed inside the chamber lid, and the thin film deposition process is progressed by this reaction being activated by the radio frequency (RF) energy supplied through an electrode mounted in the susceptor.

The second step is a step in which the thin film deposited in the first step is annealed using an RTA apparatus. The RTA apparatus is an annealing apparatus, and the thin film deposited on a substrate, and the substrate, are placed on the susceptor within the RTA apparatus, after which the annealing process is rapidly conducted at a predetermined temperature.

Hereinafter, the method for manufacturing a plasma polymerized thin film according to one example of the present invention will be described in more detail with reference to accompanying drawings.

FIG. 1 schematizes a plasma enhanced CVD apparatus used for manufacturing the plasma polymerized thin film having a low dielectric constant according to one example of the present invention.

The PECVD apparatus may include a capacitively coupled PECVD apparatus shown by a diagram in FIG. 1, but is not limited thereto, and all other types of PECVD apparatuses may be used.

The apparatus includes a first and a second carrier gas storage units (10, 11) containing a carrier gas such as He, a first and a second flow rate controllers (20, 21) for controlling the number of moles of gases passing therethrough, a first and a second bubblers (30, 31) containing solid or liquid precursors, a reactor (50) in which the reaction is progressed, and a radio frequency (RF) generator (40) for generating plasma in the reactor (50). The carrier gas storage units (10, 11), the flow rate controllers (20, 21), the bubblers (30, 31), and the reactor (50) are connected through a pipeline (60). In the reactor (50), a susceptor (51), which generates plasma around by being connected to the RF generator (40) and on which a substrate (1) may be placed, is provided. A heater (not shown) is embedded inside the susceptor (51) so as to heat the substrate (1) safely placed on the upper surface of the susceptor (51) to a temperature appropriate for deposition in the thin film deposition process. An exhaust system is provided under the reactor (50) so as to exhaust the reactant gases remaining in the reactor (50) after the deposition reaction has completed.

According to the above, an example of the method of depositing the thin film using a PECVD apparatus is as follows.

First, a substrate (1) made of silicon (P⁺⁺—Si) implanted with boron having metallic properties is washed with trichloroethylene, acetone, methanol and the like, and then placed on the susceptor (51) of the reactor (50).

The first and the second bubblers (30, 31) respectively contain the first precursor and the second precursor, and the first and the second bubblers (30, 31) are heated to temperatures sufficient to vaporize each precursor. Herein, each precursor can be contained in any one of the two bubblers (30, 31), and the heating temperature of each bubbler may be controlled depending on the types of precursors received in the bubbler.

Each first and second carrier gas storage unit (10, 11) may contain argon (Ar), helium (He), neon (Ne) or a gas combining these as a carrier gas, and the carrier gas flows via the pipeline (60) by means of the first and the second flow rate controllers (20, 21). The carrier gas flowing along the pipeline (60) generates bubbles by being introduced into the precursor solution of the bubblers (30, 31) via the bubbler inlet ports, and then flows into the pipeline (60) again loading the gaseous precursors via the bubbler outlet ports. At this time, the ratio of the first and the second precursor supplied into the reactor may be adjusted by adjusting the flow rate of the first and the second carrier gas. More specifically, the first and the second precursor may be supplied into the reactor with the flow rate ratio of the first carrier gas:the second carrier gas ranging from 1:1 to 1:5, but the flow rate ratio is not limited thereto.

The carrier gas and the vaporized precursors flowing along the pipeline (60) via the bubblers (30, 31) are sprayed through the shower heads (53) of the reactor (50), and at this time, the RF power supply (40) activates the reactant gases sprayed through the shower heads (53) by being connected to the susceptor (51). The activated precursors, after being sprayed through the shower heads (53) of the reactor (50), are deposited on the substrate (1) placed on the susceptor (51) to become a thin film. The gases remaining after the completion of the deposition reaction are exhausted to the outside via the exhaust system provided under the reactor.

At this time, the pressure of the carrier gas of the reactor (50) is preferably 0.1 to 100 torr so that the conditions for forming the thin film are optimized, and the temperature of the substrate (1) is preferably 20 to 200° C. If the temperature of the substrate (1) falls outside of the above range, the deposition rate decreases. The temperature of the substrate (1) is controlled using a heater embedded in the susceptor. In addition, the power supplied to the RF generator (40) ranges from 10 W to 500 W. If the power is above or below the above range, there may be a problem in that the formation of a low dielectric thin film having desired properties is difficult. The plasma frequency generated from the above ranges from 10 MHz to 100 MHz. The pressure of the carrier gas, the temperature of the substrate (1), and the supplying power described above are set to form the plasma having an optimal range capable of converting the precursor into reactive states and depositing the precursor-derivatives on the substrate (1), and the range may be appropriately adjusted by those skilled in the art depending on the types of the precursor. When tetrakis(trimethylsilyloxy)silane (first precursor) and cyclohexane (second precursor) are used as the precursors according to one example of the present invention, it is preferable that the plasma frequency be adjusted to be approximately 13.56 MHz.

FIG. 2 schematizes an RTA apparatus used for conducting an annealing process.

The RTA apparatus is used to perform heat treatment for a specimen, activate electrons in a semiconductor device process, change the interface between a thin film and a thin film, or between a wafer and a thin film, and increase the density of the thin film. In addition, this apparatus is also used to convert the state of the grown thin film, and decrease the loss due to an ion implantation. This RTA is conducted by heated halogen lamps and hot chucks. RTA has a short process duration time, which is different from a furnace, thereby is called as a rapid thermal process (RTP) as well. Using this heat treatment apparatus, the thin film that is plasma deposited in the prior step can be annealed.

The inside of the RTA apparatus is surrounded by a plurality of halogen lamps located around, and the lamps generate heat while emitting orange light. This RTA apparatus may anneal the thin film that is plasma deposited in the prior step and the substrate on which the thin film is placed at 300° C. to 600° C. If the annealing temperature is lower than 300° C., there may be a problem in that the properties of the initially deposited thin film are not changed, and if the annealing temperature is higher than 600° C., the structure of the thin film may be undesirably converted from the hydrocarbon-rich thin film into a SiOₓ-rich thin film. It is more preferable to rapidly increase the initial temperature to the temperature specified above within 5 minutes, and conduct the annealing for 1 to 5 minutes, in terms that the structure of the thin film can be effectively changed. The RTA annealing may be conducted under a pressure of 0.1 to 100 torr using nitrogen gas.

A third aspect of the present invention provides a semiconductor device equipped with an insulating layer consisting of the plasma polymerized thin film having high hardness and a low dielectric constant of the first aspect.

The plasma polymerized thin film of the present invention has a low dielectric constant thereby can improve the resistance-capacitance (RC) delay time of the semiconductor device.

### Advantageous Effects

Depositing a thin film using a cross-shaped precursor according to the present invention can provide a plasma polymerized thin film having significantly improved mechanical strength, and is effective in reducing complicated processes relating to pre- and post-treatments occurring in a spin casting method. In addition, the dielectric constant and the mechanical strength of the plasma polymerized thin film can be improved by annealing the thin film that is deposited with the precursor.

### DESCRIPTION OF DRAWINGS

FIG. 1 is a schematic view of a plasma enhanced chemical vapor deposition (PECVD) apparatus used for manufacturing a plasma polymerized thin film according to one example of the present invention.

FIG. 2 is a schematic view of a Rapid Thermal Annealing (RTA) apparatus used for manufacturing a plasma polymerized thin film according to one example of the present invention.

FIG. 3 is a graph showing the deposition rate of a plasma polymerized thin film manufactured according to one example of the present invention.

FIG. 4 is a graph showing the relative dielectric constant (k) of a plasma polymerized thin film manufactured according to one example of the present invention.

FIG. 5 is a graph showing the chemical structure for a plasma polymerized thin film manufactured according to one example of the present invention prior to annealing, obtained by Fourier transform infrared spectroscopy.

FIG. 6 is a graph showing the chemical structure for a plasma polymerized thin film manufactured according to one example of the present invention after annealing, obtained by Fourier transform infrared spectroscopy.

FIG. 7 is a graph showing the hardness and the elastic modulus of a plasma polymerized thin film manufactured according to one example of the present invention prior to annealing.

FIG. 8 is a graph showing the hardness and the elastic modulus of a plasma polymerized thin film manufactured according to one example of the present invention after annealing.

FIG. 9 is a summary diagram comparing polymers in a polymerization reaction using the plasma of the present invention and a general polymerization reaction.

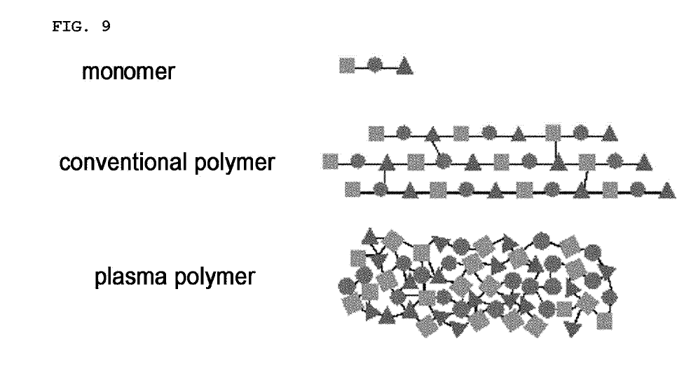

### MODE FOR DISCLOSURE

Hereinafter, a plasma deposited polymer thin film according to the present invention and a thin film obtained by annealing the plasma deposited polymer thin film, with reference to examples of the present invention. However, these examples are for illustrative purposes only, and the scope of the present invention is not limited thereto.

### Example 1

### Manufacture of TTMSS:CHex Polymer Thin Film

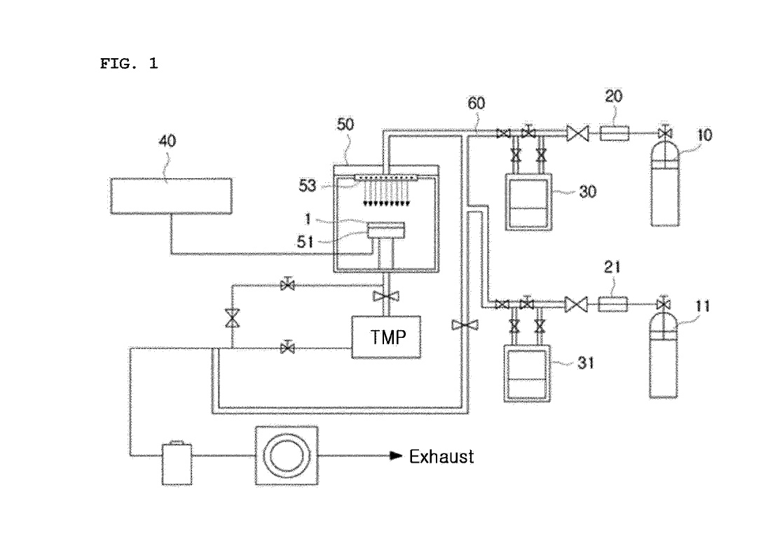

Using a PECVD apparatus shown by a diagram in FIG. 1, in a first and a second bubblers (30, 31), tetrakis(trimethylsilyloxy)silane (hereinafter referred to as ‘TTMSS’) was placed as a first precursor, and cyclohexane (hereinafter referred to as ‘CHex’) was placed as a second precursor, respectively, and the bubblers were heated to 90° C. and 55° C., respectively, vaporizing the precursor solutions. Using helium (He) gas having ultra-high purity of 99.999% as a carrier gas, the vaporized precursors were sprayed through the shower heads (53) of the reactor for plasma deposition (50) and then plasma deposited on the substrate (1). The pressure of the reactor (50) at the time was 6.6×10⁻¹ torr, and the temperature of the substrate was 35° C. In addition, the power supplied to the RF generator was applied changing from 10 W to 50 W, and the resulting plasma frequency was approximately 13.56 MHz.

The plasma polymerized thin film deposited as above was referred to as ‘TTMSS:CHex’. The thickness of the TTMSS:CHex polymer thin film was measured to be 0.4 to 0.55 μm. The assumed deposition mechanism is as follows. That is, the monomers of the precursor mixture transferred into the reactor (50) were activated to reactive species or decomposed by plasma and then condensed on the substrate (1).

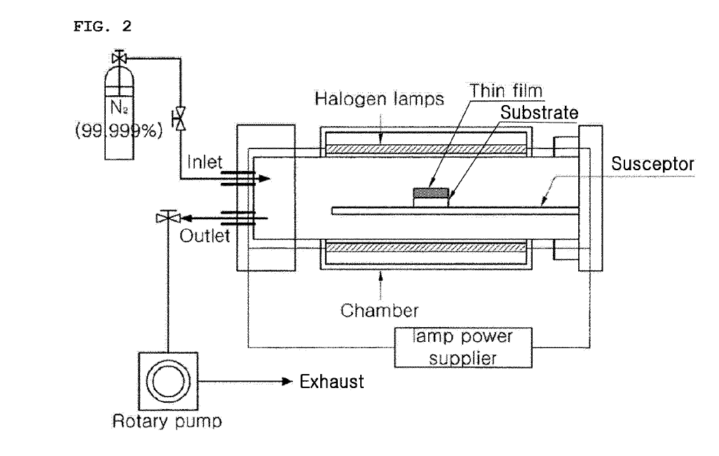

The plasma polymerized thin film TTMSS:CHex obtained as above was annealed using an RTA apparatus shown by a diagram in FIG. 2. The TTMSS:CHex deposited on the substrate was placed in an RTA system, and heat was generated using 12 halogen lamps disposed around, and the TTMSS:CHex thin film was heat treated to 500° C. for 5 minutes under nitrogen atmosphere. The pressure of the nitrogen gas was set to 1.0 torr.

The effects of RTA on this plasma polymerized TTMSS:CHex thin film were verified through the following experiments. In the accompanying drawings, an ‘as-deposited thin film’ and a ‘500° C. annealed thin film’ are defined as follows.
As-deposited thin Film: initial TTMSS:CHex thin film that was plasma deposited according to the first step of the present invention
500° C. Annealed thin film: film obtained by RTA annealing the initial plasma deposited TTMSS:CHex thin film using nitrogen gas

### Experimental Example 1

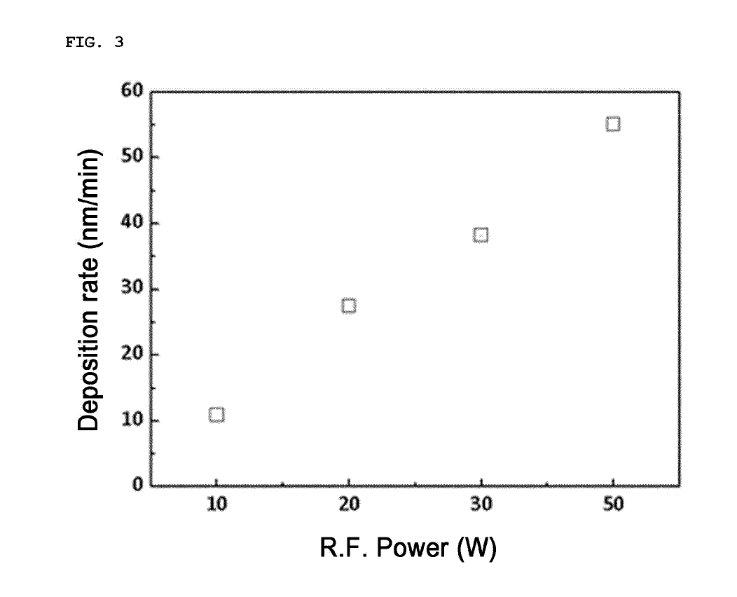

FIG. 3 is a graph showing the deposition rate for the TTMSS:CHex thin film when the TTMSS:CHex thin film was deposited using the PECVD apparatus according to Example 1. According to FIG. 3, it was verified that the deposition rate of the thin film increased as the power supplied to the RF generator (40) gradually increased.

### Experimental Example 2

Relative dielectric constants for the plasma deposited TTMSS:CHex thin film and the annealed TTMSS:CHex thin film according to Example 1 were measured.

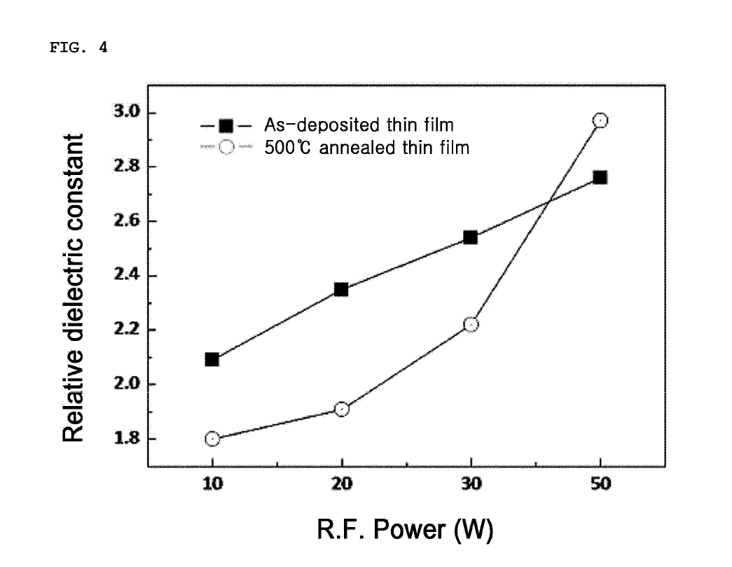

The dielectric constant was measured by applying signals having a frequency of 1 MHZ to an capacitor having a Al/TTMSS:CHex/metallic-Si structure provided on a silicon substrate (metallic-Si) having very low resistance. The result is shown in FIG. 4.

According to FIG. 4, the relative dielectric constant (k) increased from 2.09 to 2.76 as the power for the plasma deposited TTMSS:CHex thin film increased, and the relative dielectric constant of the annealed TTMSS:CHex thin film increased from 1.80 to 2.97. As a result, it was seen that, the relative dielectric constant generally decreased when the plasma deposited TTMSS:CHex thin film was RTA annealed.

### Experimental Example 3

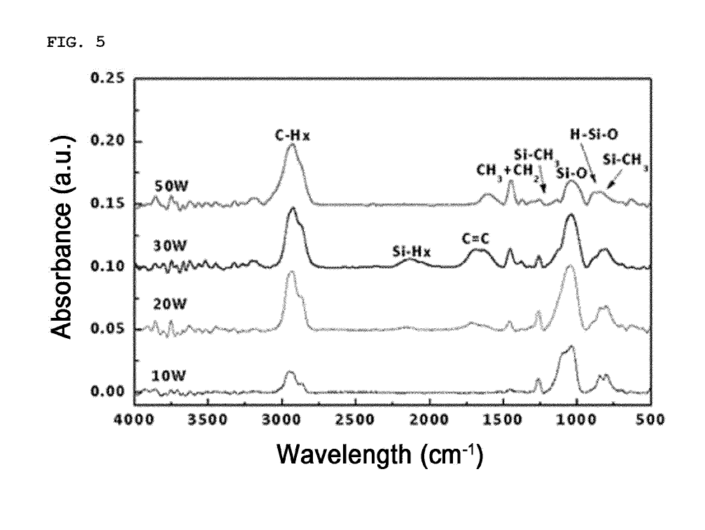

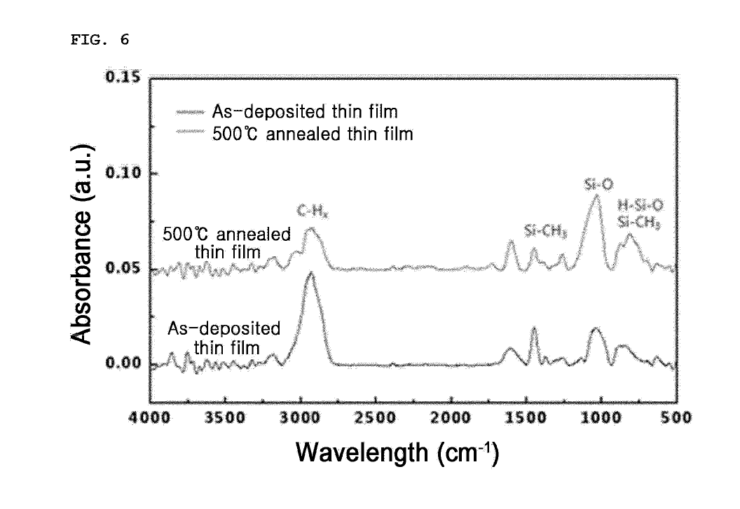

For the plasma deposited TTMSS:CHex thin film and the annealed TTMSS:CHex thin film according to Example 1, the chemical structures thereof obtained by Fourier transform infrared spectroscopy were identified, and the results are shown in FIG. 5 and FIG. 6.

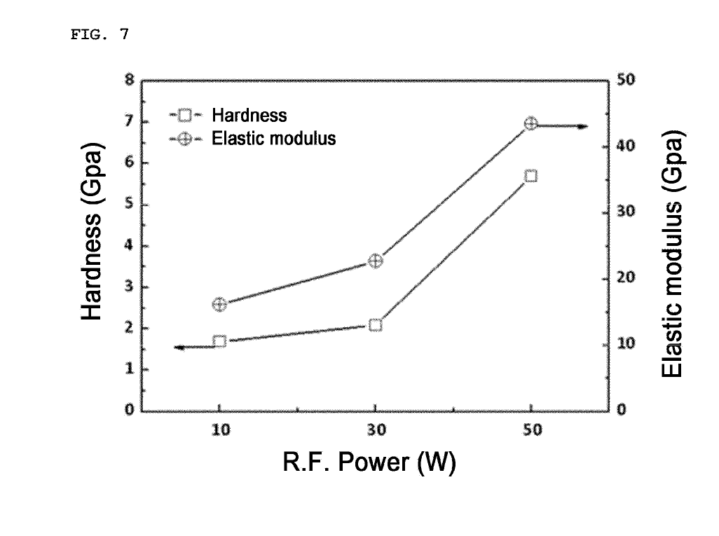

First, FIG. 5 is a graph showing the chemical structure of the plasma deposited TTMSS:CHex thin film deposited with various applying powers. As shown in the graph, it can be seen that, in the plasma deposited TTMSS:CHex thin film, C-Hx bonding structures (hydrocarbon) and Si—O bonding structures basically have the majority. In particular, it was seen that as the power increased, the amounts of hydrocarbon increased since the C-Hx bonding structure increased. As shown in FIG. 7 seen later, it is considered that the hardness and the elastic modulus of the thin film would be able to increase as the amounts of hydrocarbon increased.

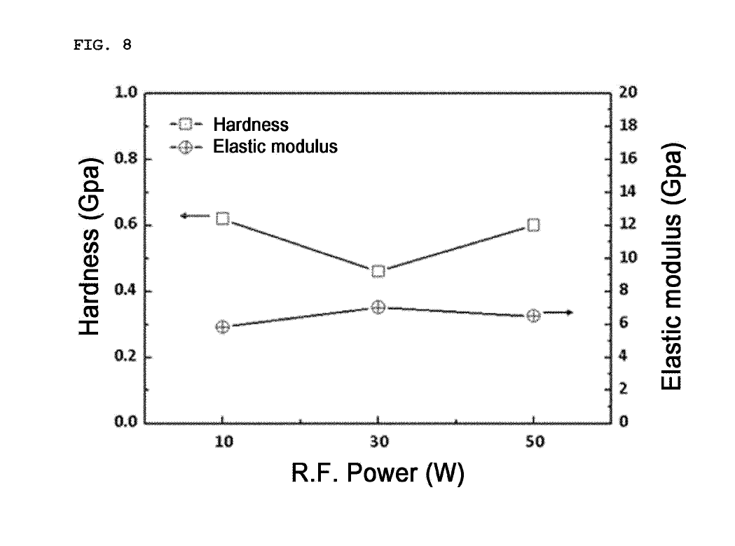

In FIG. 6, it was shown that, in all the plasma deposited TTMSS:CHex thin film and the annealed TTMSS:CHex thin film, stretching vibrations for the respective chemical structures are generated at the same positions over the entire wavenumber range. This shows that the plasma deposited TTMSS:CHex thin film and the annealed TTMSS:CHex thin film all have similar bonding structures. However, specifically, it was seen that the annealed thin film had a relatively higher Si—O bonding structure compared to a C-Hx bonding structure. As shown in FIG. 8 seen later, it was verified that the dielectric constant generally decreased and the hardness of the thin film was also reduced after annealing, and it is considered that the hardness of the thin film was more or less reduced by the pores being formed where the hydrocarbon was sublimated, as the hydrocarbon was sublimated due to the heat treatment. However, in tetrakis(trimethylsilyloxy)silane, which is one of the precursors of the thin film, the structure of the precursor molecule is expected to have a cross shape in which a Si atom at the center is linked to oxygen atoms in four directions, and the bonding around Si is considered to be solidly maintained due to this structural stability. Therefore, it is considered that maintaining the bonding around Si even after annealing at a high temperature prevents the hardness and the elastic modulus of the thin film from being seriously reduced.

### Experimental Example 4

The hardness and the elastic modulus for the plasma deposited TTMSS:CHex thin film according to Example 1 were measured.

For the plasma deposited TTMSS:CHex thin film, the hardness of the thin film was measured using a nano-indenter, and furthermore, the elastic modulus of the thin film was also measured using a nano-indenter. The results are shown in FIG. 7.

According to FIG. 7, it was seen that the hardness of the plasma deposited TTMSS:CHex thin film increased from 1.6 GPa to 5.6 GPa as the applying power increased, and the elastic modulus also greatly increased from 16 GPa to 44 GPa. Particularly, it is considered to be due to the increase of the C-Hx bonding structure within the thin film with the increase of power, as described in Experimental Example 3.

### Experimental Example 5

The hardness and the elastic modulus for the annealed TTMSS:CHex thin film according to Example 1 were measured.

For the annealed TTMSS:CHex thin film, the hardness of the thin film was measured using a nano-indentor, as in Experimental Example 4, and furthermore, the elastic modulus of the thin film was measured. The results are shown in FIG. 8.

According to FIG. 8, the hardness of the annealed TTMSS:CHex thin film was reduced and then increased again as the applying power increased, and it was seen that the value was maintained between 0.45 GPa and 0.6 GPa. For the elastic modulus, it was seen that the value was maintained between 6 GPa and 7 GPa.

The hardness and the elastic modulus for the annealed TTMSS:CHex thin film were reduced compared to those for the plasma deposited TTMSS:CHex thin film examined in Experimental Example 4, and as described in Experimental Example 3, it is considered to be the result of C-Hx bonding structure reduction within the thin film due to the sublimation of hydrocarbon from annealing. However, although the hardness and the elastic modulus were reduced after annealing, the thin film of the present invention sill had mechanical properties sufficient to be used in a semiconductor process. It was verified that the thin film provided in the present invention was an excellent thin film having a low dielectric constant and also having high mechanical strength by the bonding around Si being solidly maintained even after annealing due to the structural characteristics of tetrakis(trimethylsilyloxy)silane (TTMSS). The thin film provided in the present invention was shown to have excellent mechanical strength when compared with existing thin films having relative dielectric constants (k=1.8 to 2.5) and hardness after annealing (0.12 to 0.57 GPa), which are provided in a literature published by K. Maex research group (K. Maex, M. R. Baklanov, D. Shamiryan, F. Iacopi, S. H. Brongersm and Z. S. Yanovitskaya J. Appl. Phys, 93 (2003) 8793).

Reference

| | | | |
|---|---|---|---|
| 1: | Substrate | 10, 11: | Carrier GasStorage Unit |
| 20, 21: | Flow Rate Controller | 30, 31: | Bubbler |
| 40: | RF Generator | 50: | Reactor |
| 51: | Susceptor | 53: | Shower Head |

| | |
|---|---|
| 60: | Pipeline |

1. A plasma polymerized thin film having high hardness and a low dielectric constant manufactured using a first precursor represented by the following Chemical Formula 1: 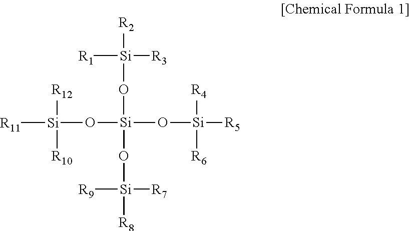
wherein, in the formula, R₁ to R₁₂ are each independently H or C₁-C₅ alkyl.

2. The plasma polymerized thin film having high hardness and a low dielectric constant of claim 1, which is manufactured using a second precursor, which is hydrocarbon in a liquid state present within a bubbler of a plasma polymerization apparatus, together with the first precursor.

3. The plasma polymerized thin film having high hardness and a low dielectric constant of claim 2, wherein the conditions within the bubbler are 250° C. or less and 5 atmosphere or less.

4. The plasma polymerized thin film having high hardness and a low dielectric constant of claim 2, wherein the second precursor is C₆-C₁₂ alkane, alkene, cycloalkene or cycloalkene.

5. The plasma polymerized thin film having high hardness and a low dielectric constant of claim 2, wherein the second precursor is cyclohexane.

6. The plasma polymerized thin film having high hardness and a low dielectric constant of claim 1, which is manufactured by a polymerization reaction using plasma.

7. The plasma polymerized thin film having high hardness and a low dielectric constant of claim 1, which is annealed after plasma polymerization.

8. The plasma polymerized thin film having high hardness and a low dielectric constant of claim 2, which is manufactured by adjusting the flow rate ratio of a first carrier gas to a second carrier gas to correspond to the intended ratio of the supplied first precursor to the second precursor, wherein the flow rate ratio of the carrier gases is 1:1 to 1:5.

9. The plasma polymerized thin film having high hardness and a low dielectric constant of claim 1, wherein the first precursor is tetrakis(trimethylsilyloxy)silane.

10. The plasma polymerized thin film having high hardness and a low dielectric constant of claim 1, wherein the hardness of the thin film ranges from 0.1 to 10 GPa, and the relative dielectric constant ranges from 1.5 to 3.5.

11. A method for manufacturing a plasma polymerized thin film having high hardness and a low dielectric constant, comprising:
a first step of depositing the plasma polymerized thin film on a substrate by polymerizing a first precursor represented by Chemical Formula 1 through plasma; and
a second step of annealing the deposited thin film: 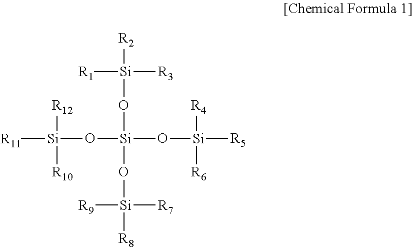
wherein, in the formula, R₁ to R₁₂ are each independently H or C₁-C₅ alkyl.

12. The manufacturing method of claim 11 wherein, in the first step, the plasma polymerized thin film is deposited on a substrate by polymerizing a second precursor, which is hydrocarbon in a liquid state present within a bubbler of a plasma polymerization apparatus, together with the first precursor.

13. The manufacturing method of claim 11, wherein the first step uses a plasma enhanced CVD method.

14. The manufacturing method of claim 12, wherein the second precursor is C₆-C₁₂ alkane, alkene, cycloalkane or cycloalkene.

15. The manufacturing method of claim 12, wherein the second precursor is cyclohexane.

16. The manufacturing method of claim 12, wherein the first precursor is tetrakis(trimethylsilyloxy)silane.

17. The manufacturing method of claim 12, wherein the first step includes,
an A step of vaporizing the first precursor and the second precursor in bubblers;
a B step of supplying the vaporized precursors into a reactor for plasma deposition from the bubblers; and
a C step of forming the plasma polymerized thin film on the substrate in the reactor using the plasma of the reactor.

18. The manufacturing method of claim 17, wherein power supplied to the reactor ranges from 10 W to 500 W.

19. The manufacturing method of claim 11, wherein the second step is performed by heat treating the substrate at 300° C. to 600° C.

20. A semiconductor device equipped with an insulating layer consisting of the plasma polymerized thin film having high hardness and a low dielectric constant of claim 1.
